(19) United States
(12) Patent Application Publication
(10) Pub. No.: US 2026/0123040 A1
(43) Pub. Date: Apr. 30, 2026

(54) SEMICONDUCTOR DEVICE

(71) Applicant: Renesas Electronics Corporation, Tokyo (JP)

(72) Inventors: Hidenori SATO, Tokyo (JP); Yuki YAMAMOTO, Tokyo (JP)

(21) Appl. No.: 19/298,303

(22) Filed: Aug. 13, 2025

(30) Foreign Application Priority Data
Oct. 29, 2024 (JP) 2024-189838

(51) Int. Cl. H10D 84/83

(52) U.S. Cl. CPC H10D 84/835; H10D 84/839

(57) ABSTRACT

An LDMOSFET is formed at a main surface of a semiconductor substrate. The LDMOSFET includes an n-type drain region, an n-type source region, an n-type drift region, a first p-type well region, and a second p-type well region, all formed in an n-type semiconductor layer. The n-type drift region is in contact with a bottom surface of the n-type drain region, the second p-type well region is in contact with a bottom surface of the n-type source region, and the first p-type well region is in contact with a bottom surface of the n-type drift region and a bottom surface of the second p-type well region. A p-type impurity concentration in the first p-type well region is lower than a p-type impurity concentration in the second p-type well region and is lower than an n-type impurity concentration in the n-type semiconductor layer.

### CROSS-REFERENCE TO RELATED APPLICATIONS

The disclosure of Japanese Patent Application No. 2024-189838 filed on October 29, 2024, including the specification, drawings and abstract is incorporated herein by reference in its entirety.

### BACKGROUND

The present invention relates to a semiconductor device, which can be suitably used for a semiconductor device having a transistor as a power switching element.

In some cases, transistors that configure other circuits are also formed together on a semiconductor substrate where a power switching element is formed.

There are disclosed techniques listed below.

[Patent Document 1] Japanese Unexamined Patent Application Publication No. 2015-23451

Patent Document 1 discloses a technology related to a semiconductor device equipped with an output MOS transistor and a short-circuit transistor.

### SUMMARY

It is desirable to improve the performance of semiconductor devices having power switching elements.

Other problems and novel features will become apparent from the description of this specification and the accompanying drawings.

According to one embodiment, a semiconductor device includes a semiconductor substrate, a first MOSFET and a second MOSFET formed at a main surface of the semiconductor substrate, and a back electrode formed on a back surface of the semiconductor substrate. The semiconductor substrate has a substrate region of a first conductivity type and a semiconductor layer of the first conductivity type formed on the substrate region. The first MOSFET includes a gate electrode formed on the semiconductor layer via a gate insulating film, a first source region and a first drain region of the first conductivity type formed in the semiconductor layer, a drift region of the first conductivity type formed in the semiconductor layer, and a first well region and a second well region of a second conductivity type formed in the semiconductor layer. The drift region is in contact with a bottom surface of the first drain region, the first well region is in contact with the bottom surface of the first source region, and the second well region is in contact with the bottom surface of the drift region and the bottom surface of the first well region. The second MOSFET includes a trench gate electrode formed in a trench of the semiconductor layer via a second gate insulating film and a second source region of the first conductivity type formed in the semiconductor layer. An impurity concentration of the second conductivity type in the first well region is higher than an impurity concentration of the second conductivity type in the second well region. The impurity concentration of the second conductivity type in the second well region is lower than an impurity concentration of the first conductivity type in the semiconductor layer.

According to one embodiment, the performance of the semiconductor device can be improved.

### BRIEF DESCRIPTION OF THE DRAWINGS

FIG. 1 is a circuit diagram showing a circuit example using a power switching element.

FIG. 2 is a main portion cross-sectional view of a semiconductor device of a first embodiment.

FIG. 3 is a main portion cross-sectional view of the semiconductor device of the first embodiment.

FIG. 4 is a graph showing the p-type impurity concentration distribution in the p-type well region of the semiconductor device of the first embodiment.

FIG. 5 is a graph showing the p-type impurity concentration distribution in the p-type well region of the semiconductor device of the first embodiment.

FIG. 6 is a graph showing the p-type impurity concentration distribution in the p-type well region of the semiconductor device of the second embodiment.

FIG. 7 is a graph showing the p-type impurity concentration distribution in the p-type well region of the semiconductor device of the second embodiment.

### DETAILED DESCRIPTION

In the following embodiments, for convenience, when necessary, the description will be divided into multiple sections or embodiments, but unless specifically stated otherwise, they are not unrelated to each other, and one is related to the other as a part or all of a modified example, detail, supplementary explanation, etc. Also, in the following embodiments, when referring to the number of elements, etc. (including the number, numerical values, quantities, ranges, etc.), unless specifically stated otherwise and clearly limited to a specific number in principle, it is not limited to that specific number and may be not less than or equal to the specific number. Furthermore, in the following embodiments, the constituent elements (including element steps, etc.) are not necessarily essential unless specifically stated otherwise and clearly considered essential in principle. Similarly, in the following embodiments, when referring to the shapes, positional relationships, etc. of components, unless specifically stated otherwise and clearly considered not so in principle, it is assumed to include those substantially approximate or similar to those shapes, etc. The same applies to the above numerical values and ranges.

Hereinafter, embodiments will be described in detail with reference to the drawings. In all the drawings for explaining the embodiments, members having the same functions are denoted by the same reference numerals, and repetitive descriptions thereof are omitted. Also, in the following embodiments, descriptions of the same or similar parts will not be repeated in principle except when particularly necessary.

In the drawings used in the embodiments, hatching may be omitted even in the case of cross-sectional views to make the drawings easier to see. Also, even in the case of plan views, hatching may be used to make the drawing easier to see.

In addition, "plan view" corresponds to the view from a plane substantially parallel to the main surface or back surface of the semiconductor substrate SUB. Also, "bottom surface" and "lower surface" have the same meaning.

In this application, MOSFET (Metal Oxide Semiconductor Field Effect Transistor) or LDMOSFET (Laterally Diffused Metal Oxide Semiconductor Field Effect Transistor) includes not only MOSFETs using an oxide film as a gate insulating film but also MOSFETs using insulating films other than oxide films as gate insulating films. LDMOSFET may also be referred to as HV-MOSFET (High Voltage Metal Oxide Semiconductor Field Effect Transistor) or DEMOSFET (Drain Extended Metal Oxide Semiconductor Field Effect Transistor).

In this application, the n-type impurity concentration is the effective n-type impurity concentration, and the p-type impurity concentration is the effective p-type impurity concentration. In a semiconductor region containing both n-type and p-type impurities, when the majority carriers are electrons (n-type impurities), the difference between the number of n-type impurities per unit volume and the number of p-type impurities per unit volume is the effective n-type impurity concentration. In a semiconductor region containing both n-type and p-type impurities, when the majority carriers are holes (p-type impurities), the difference between the number of n-type impurities per unit volume and the number of p-type impurities per unit volume is the effective p-type impurity concentration.

### FIRST EMBODIMENT

### CIRCUIT EXAMPLE

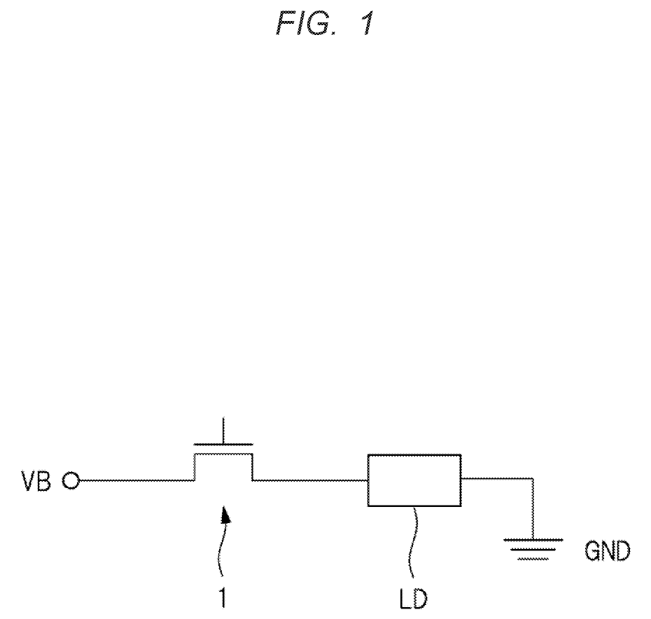

As shown in FIG. 1, a power MOSFET 1 is interposed between a power supply potential VB and a load LD. The power supply potential VB is supplied from a battery or the like. Specifically, the drain of the power MOSFET 1 is connected to the power supply potential VB, and the source of the power MOSFET 1 is connected to the load LD. The load LD is also connected to the ground potential GND. The load LD is interposed between the ground potential GND and the power MOSFET 1.

Both the power supply potential VB and the ground potential GND are fixed potentials, and the power supply potential VB is higher than the ground potential GND. For example, the ground potential GND is 0 V, and the power supply potential VB is a positive fixed potential.

The power MOSFET 1 is a transistor configuring a power switching element. When the gate voltage of the power MOSFET 1 is lower than the threshold voltage (for example, 0 V), the power MOSFET 1 is in an off-state (non-conductive state), and no current flows to the load LD. When a gate voltage equal to or greater than the threshold voltage is supplied to the gate of the power MOSFET 1, the power MOSFET 1 is in an on-state (conductive state). When the power MOSFET 1 is in an on-state, current flows to the load LD through the power MOSFET 1.

### STRUCTURE OF THE SEMICONDUCTOR DEVICE

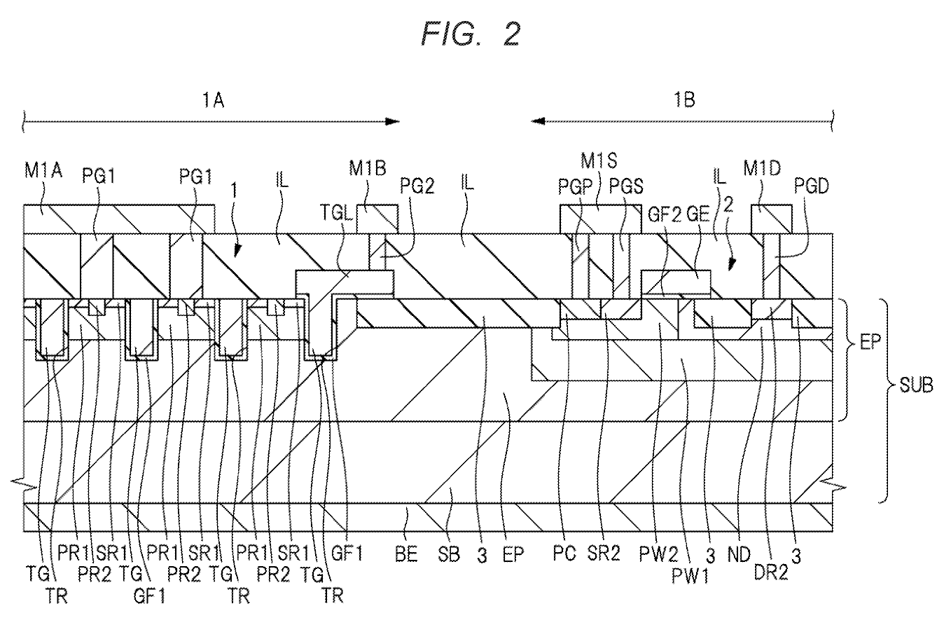

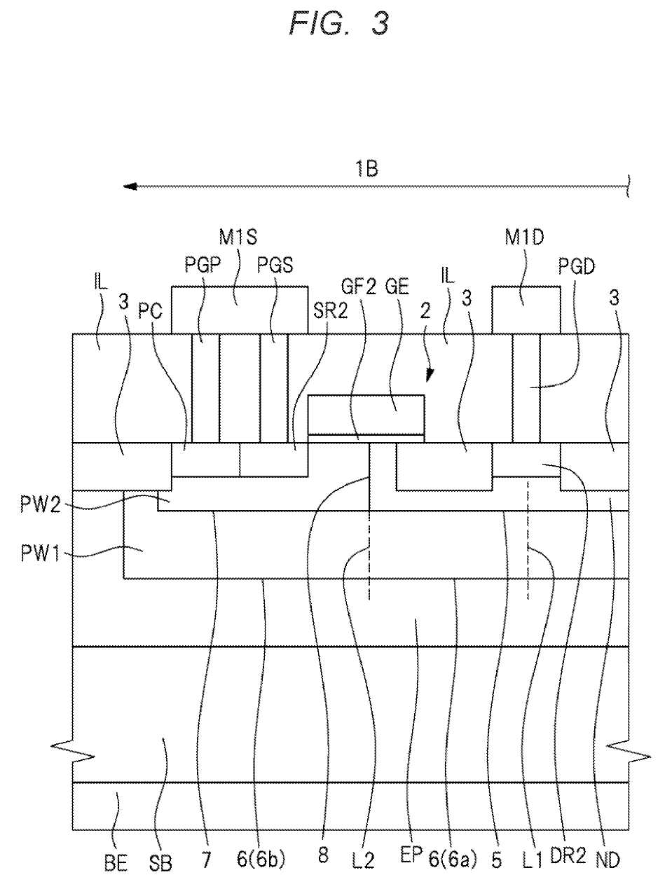

The semiconductor device of the first embodiment will be described with reference to FIGS. 2 and 3. FIG. 3 is an enlarged partial cross-sectional view of a part of FIG. 2. In FIG. 3, hatching is omitted.

As shown in FIGS. 2 and 3, the semiconductor device of the first embodiment includes a semiconductor substrate SUB, a power MOSFET 1, an LDMOSFET 2, an STI region 3, an insulating film IL, and a back electrode BE.

As shown in FIGS. 2 and 3, the semiconductor substrate SUB is an n-type semiconductor substrate, and includes an n-type substrate body (substrate region) SB and an n-type semiconductor layer EP formed on the n-type substrate body SB.

The n-type substrate body SB is made of n-type single crystal silicon into which n-type impurities such as phosphorus (P) or arsenic (As) are introduced. A thickness of the n-type substrate body SB is almost uniform. The n-type semiconductor layer EP is made of n-type single crystal silicon formed on the n-type substrate body SB. An n-type impurity concentration of the n-type substrate body SB is higher than an n-type impurity concentration of the n-type semiconductor layer EP. The n-type semiconductor layer EP and the n-type substrate body SB are in contact with each other.

The main surface of the semiconductor substrate SUB is synonymous with the main surface of the n-type semiconductor layer EP. Also, the back surface of the semiconductor substrate SUB is synonymous with the back surface of the n-type substrate body SB. The main surface and the back surface of the semiconductor substrate SUB are located on opposite sides. A back electrode BE is formed on the back surface of the semiconductor substrate SUB. The n-type substrate body SB and the back electrode BE are in contact with each other. The thickness direction of the semiconductor substrate corresponds to the direction from one of the main surface or back surfaces of the semiconductor substrate SUB to the other, and is approximately perpendicular to the main surface or back surface of the semiconductor substrate SUB.

The STI (Shallow Trench Isolation) region 3 is formed of an insulating film buried in a trench formed in the semiconductor substrate SUB. Instead of the STI region 3, a LOCOS (Local Oxidation of Silicon) region can also be applied.

The main surface of the semiconductor substrate SUB includes an element region 1A where a transistor functioning as a power switching element (here, a power MOSFET 1) is formed, and an element region 1B where an LDMOSFET 2 configuring other circuits (e.g., control circuits) is formed. In plan view, the element region 1A and the element region 1B are separated from each other.

Next, the configuration of the power MOSFET 1 formed in the element region 1A will be described.

The power MOSFET 1 is a trench gate type MOSFET. The power MOSFET 1 includes a trench gate electrode TG, a gate insulating film GF1, an n-type source region SR1, a p-type semiconductor region PR1, a p-type semiconductor region PR2, and a gate wiring part TGL.

The trench gate electrode TG is formed in a trench TR formed at the main surface of the semiconductor substrate SUB via the gate insulating film GF1. The trench TR extends in the direction from the main surface to the back surface of the semiconductor substrate SUB. The bottom surface of the trench TR is deeper than the bottom surface of the p-type semiconductor region PR1. The gate insulating film GF1 is formed on the bottom surface and the side surface of the trench TR. The trench gate electrode TG is made of, for example, a polycrystalline silicon film into which n-type impurities are introduced.

The n-type source region SR1, the p-type semiconductor region (p-type body region) PR1, and the p-type semiconductor region PR2 are formed in the n-type semiconductor layer EP. The n-type source region SR1 and the p-type semiconductor region PR2 are formed on and in contact with the p-type semiconductor region PR1. The p-type impurity concentration of the p-type semiconductor region PR2 is higher than the p-type impurity concentration of the p-type semiconductor region PR1. The n-type impurity concentration of the n-type source region SR1 is higher than the n-type impurity concentration of the n-type semiconductor layer EP.

The n-type source region SR1 and the p-type semiconductor region PR1 are in contact with the gate insulating film GF1 formed on the side surface of the trench TR. The n-type source region SR1 is interposed between the p-type semiconductor region PR2 and the trench TR. The n-type source region SR1 is adjacent to the trench gate electrode TG via the gate insulating film GF1. The p-type semiconductor region PR1 is located under the n-type source region SR1 and is adjacent to the trench gate electrode TG via the gate insulating film GF1. The bottom surface of the n-type source region SR1 is the boundary between the n-type source region SR1 and the p-type semiconductor region PR1. Therefore, a PN junction is formed at the bottom surface of the n-type source region SR1. Under the bottom surface of the p-type semiconductor region PR1, a part of the n-type semiconductor layer EP (n-type semiconductor region) exists. Therefore, a PN junction is formed at the bottom surface of the p-type semiconductor region PR1.

The n-type semiconductor layer EP is located under the p-type semiconductor region PR1, and the n-type substrate body SB is located under the p-type semiconductor region PR1 function as the n-type drain region of the power MOSFET 1. The channel of the power MOSFET 1 is formed along the trench TR in the p-type semiconductor region PR1. The operating current of the power MOSFET 1 flows between the n-type source region SR1 and the n-type substrate body SB through the channel formed in the p-type semiconductor region PR1 and the n-type semiconductor layer EP. Therefore, the operating current of the power MOSFET 1 flows along the thickness direction of the semiconductor substrate SUB.

The back electrode BE can function as a drain electrode electrically connected to the drain of the power MOSFET 1. The back electrode BE is formed on the entire back surface of the semiconductor substrate SUB. The power MOSFET 1 may be configured by connecting a plurality of unit transistor cells in parallel.

The gate wiring part TGL is integrally formed with and electrically connected to the trench gate electrode TG. The trench gate electrode TG is formed in the trench TR. On the other hand, the gate wiring part TGL is disposed on the semiconductor substrate SUB outside the trench TR. A part of the gate wiring part TGL is located on the STI region 3.

The insulating film IL is formed on the main surface of the semiconductor substrate SUB and covers the power MOSFET 1.

Next, the configuration of the LDMOSFET 2 formed in the element region 1B will be described.

The LDMOSFET 2 includes a p-type well region PW1, a p-type well region PW2, an n-type drift region ND, an n-type drain region DR2, an n-type source region SR2, a p-type semiconductor region PC, a gate electrode GE, and a gate insulating film GF2.

The p-type well region (p-type semiconductor region) PW1, the p-type well region (p-type semiconductor region) PW2, the n-type drift region (n-type semiconductor region) ND, the n-type drain region (n-type semiconductor region) DR2, the n-type source region (n-type semiconductor region) SR2, and the p-type semiconductor region (p-type semiconductor region) PC are formed in the n-type semiconductor layer EP. The gate electrode GE is formed on the n-type semiconductor layer EP via the gate insulating film GF2. The insulating film IL is formed on the main surface of the semiconductor substrate SUB and covers the LDMOSFET 2.

The p-type well region PW1 is formed in the upper part of the n-type semiconductor layer EP. Under a bottom surface 6 of the p-type well region PW1, a part of the n-type semiconductor layer EP (n-type semiconductor region) exists. Therefore, a PN junction is formed at the bottom surface 6 of the p-type well region PW1.

The p-type well region PW1 surrounds the p-type well region PW2 and the n-type drift region ND. That is, in plan view, the p-type well region PW2 and the n-type drift region ND are included in the p-type well region PW1. The bottom surface 7 of the p-type well region PW2 is shallower than the bottom surface 6 of the p-type well region PW1, and the bottom surface 5 of the n-type drift region ND is shallower than the bottom surface 6 of the p-type well region PW1. Under the bottom surface 5 of the n-type drift region ND and the bottom surface 7 of the p-type well region PW2, a part of the p-type well region PW1 exists. The bottom surface 7 of the p-type well region PW2 is in contact with the p-type well region PW1, and the bottom surface 5 of the n-type drift region ND is in contact with the p-type well region PW1. The p-type impurity concentration of the p-type well region PW2 is higher than the p-type impurity concentration of the p-type well region PW1. The n-type impurity concentration of the n-type drift region ND is higher than the n-type impurity concentration of the n-type semiconductor layer EP. The bottom surface 5 of the n-type drift region ND is the boundary between the n-type drift region ND and the p-type well region PW1. Therefore, a PN junction is formed at the bottom surface 5 of the n-type drift region ND.

The p-type well region PW2 surrounds the n-type source region SR2 and the p-type semiconductor region PC. That is, in plan view, the n-type source region SR2 and the p-type semiconductor region PC are included in the p-type well region PW2. The bottom surface of the n-type source region SR2 is shallower than the bottom surface 7 of the p-type well region PW2, and the bottom surface of the p-type semiconductor region PC is shallower than the bottom surface 7 of the p-type well region PW2. Under the bottom surface of the n-type source region SR2 and the bottom surface of the p-type semiconductor region PC, a part of the p-type well region PW2 exists. The bottom surface of the n-type source region SR2 and the bottom surface of the p-type semiconductor region PC are in contact with the p-type well region PW2. The upper surface of the n-type source region SR2 and the upper surface of the p-type semiconductor region PC reach the main surface of the semiconductor substrate SUB. The n-type impurity concentration of the n-type source region SR2 is higher than the n-type impurity concentration of the n-type drift region ND. The p-type impurity concentration of the p-type semiconductor region PC is higher than the p-type impurity concentration of the p-type well region PW2. The p-type semiconductor region PC can function as a contact part of the p-type well region PW2. The bottom surface of the n-type source region SR2 is the boundary between the n-type source region SR2 and the p-type well region PW2. Therefore, a PN junction is formed at the bottom surface of the n-type source region SR2.

The n-type drift region ND surrounds the n-type drain region DR2. That is, in plan view, the n-type drain region DR2 is included in the n-type drift region ND. The bottom surface of the n-type drain region DR2 is shallower than the bottom surface of the n-type drift region ND. Under the bottom surface of the n-type drain region DR2, a part of the n-type drift region ND exists. The bottom surface of the n-type drain region DR2 is in contact with the n-type drift region ND. The upper surface of the n-type drain region DR2 reaches the main surface of the semiconductor substrate SUB. The n-type impurity concentration of the n-type drain region DR2 is higher than the n-type impurity concentration of the n-type drift region ND.

The n-type drift region ND and the p-type well region PW2 are adjacent to each other in the gate length direction of the LDMOSFET 2. The gate length direction of the LDMOSFET 2 corresponds to the gate length direction of the gate electrode GE, and the gate width direction of the LDMOSFET 2 corresponds to the gate width direction of the gate electrode GE.

The p-type well region PW2 can function as a back gate. It can also serve as a punch-through stopper to suppress the extension of the depletion layer from the drain to the source of the LDMOSFET 2. The channel of LDMOSFET 2 is formed in the upper part of the p-type well region PW2, which is located between the n-type source region SR2 and the n-type drain region DR2 and under the gate electrode GE. Hereinafter, the region where the channel of the LDMOSFET 2 is formed is referred to as the channel formation region. The n-type source region SR2 is adjacent to the channel formation region of the LDMOSFET 2. The n-type drain region DR2 and the n-type source region SR2 are separated from each other in the gate length direction of the LDMOSFET 2.

In the case of FIGS. 2 and 3, the p-type semiconductor region PC and the n-type source region SR2 are adjacent to each other in the gate length direction of the LDMOSFET 2. In this case, in plan view, the n-type source region SR2 is located between the gate electrode GE and the p-type semiconductor region PC. There may also be cases where the p-type semiconductor region PC and the n-type source region SR2 are not adjacent to each other in the gate length direction of the LDMOSFET 2 and are alternately arranged in the gate width direction of the LDMOSFET 2.

The gate electrode GE is formed on the main surface of the semiconductor substrate SUB between the n-type source region SR2 and the n-type drain region DR2 via a gate insulating film GF2. The gate insulating film GF2 is made of, for example, a silicon oxide film. The gate electrode GE is made of, for example, a single film of polycrystalline silicon (doped polysilicon film) or a laminated film of polycrystalline silicon and a metal silicide layer. In plan view, a part of the gate electrode GE overlaps the n-type drift region ND, and another part overlaps the p-type well region PW2.

In plan view, the STI region 3 is disposed between the channel formation region of the LDMOSFET 2, and the n-type drain region DR2, and a part of the gate electrode GE is located on the STI region 3. The n-type drift region ND exists under the STI region 3, which is interposed between the channel formation region of the LDMOSFET 2, and the n-type drain region DR2. The bottom surface of the n-type drain region DR2 is in contact with the n-type drift region ND, and the side surface of the n-type drain region DR2 is in contact with the STI region 3. Therefore, the n-type drift region ND under the STI region 3 can also function as a conduction path between the channel of the LDMOSFET 2 and the n-type drain region DR2.

In FIGS. 2 and 3, there is a case where the gate insulating film GF2 is interposed between the STI region 3 and the gate electrode GE, but there may also be cases where the gate insulating film GF2 is not interposed between the STI region 3 and the gate electrode GE. Additionally, a sidewall spacer made of an insulating film (not shown) may be formed on the side surface of the gate electrode GE.

A part of the p-type well region PW2 is located under the gate electrode GE, and a part of the n-type drift region ND is located under the gate electrode GE. A PN junction is formed at the boundary between the p-type well region PW2 and the n-type drift region ND. The boundary between the p-type well region PW2 and the n-type drift region ND is located under the gate electrode GE and extends in the gate width direction of the LDMOSFET 2.

In plan view, the gate electrode GE is disposed between the n-type source region SR2 and the n-type drain region DR2. When a voltage equal to or greater than the threshold voltage is applied to the gate electrode GE, a channel is formed in the upper part of the p-type well region PW2 located under the gate electrode GE. The n-type source region SR2 and the n-type drain region DR2 conduct with each other through the channel and the n-type drift region ND.

In the gate length direction of the LDMOSFET 2, the n-type drift region ND is interposed between the p-type well region PW2 and the n-type drain region DR2. Therefore, the n-type drift region ND exists between the channel formation region of the LDMOSFET 2, and the n-type drain region DR2. Consequently, in the gate length direction of the LDMOSFET 2, the channel formation region and the n-type drift region ND exist between the n-type source region SR2, and the n-type drain region DR2, with the channel formation region located between the n-type source region SR2 and the n-type drift region ND.

Additionally, metal silicide layers (not shown) may be formed on the n-type drain region DR2, on the n-type source region SR2, and on the p-type semiconductor region PC. These metal silicide layers can be formed using salicide (Self Aligned Silicide) technology.

Next, the structure over the semiconductor substrate SUB will be described.

As shown in FIGS. 2 and 3, the semiconductor device of the first embodiment further includes a plug (contact plug) PG1, a plug (contact plug) PG2, a plug (contact plug) PGD, a plug (contact plug) PGP, a plug (contact plug) PGS, and a wiring M1A, a wiring M1B, a wiring M1D, and a wiring M1S.

The insulating film IL is formed on the main surface of the semiconductor substrate SUB and covers the trench gate electrode TG, the gate wiring part TGL, and the gate electrode GE. The insulating film IL includes, for example, a silicon nitride film and a silicon oxide film on the silicon nitride film. The upper surface of the insulating film IL is planarized.

A plurality of contact holes (through holes) are formed in the insulating film IL, and a plurality of conductive plugs are formed in these contact holes. The plurality of plugs include the plug PG1, the plug PG2, the plug PGD, the plug PGP, and the plug PGS. Each of the plug PG1, the plug PG2, the plug PGD, the plug PGP, and the plug PGS penetrates through the insulating film IL.

The plug PGD is located on the n-type drain region DR2 and is electrically connected to the n-type drain region DR2. The plug PGS is located on the n-type source region SR2 and is electrically connected to the n-type source region SR2. The plug PGP is located on the p-type semiconductor region PC and is electrically connected to the p-type semiconductor region PC. Therefore, the plug PGP is electrically connected to the p-type well region PW2 via the p-type semiconductor region PC.

The plug PG1 is located across the p-type semiconductor region PR2 and the n-type source region SR1 and is electrically connected to both the p-type semiconductor region PR2 and the n-type source region SR1. The plug PG2 is located on the gate wiring part TGL and is electrically connected to the gate wiring part TGL.

Although a plug is also located on the gate electrode GE, the plug on the gate electrode GE is not shown in FIGS. 2 and 3.

The plurality of wirings are formed on the insulating film IL. The plurality of wirings include a wiring M1A, a wiring M1B, a wiring M1D, and a wiring M1S.

The wiring M1A is electrically connected to both the n-type source region SR1 and the p-type semiconductor region PR2 via the plug PG1. Therefore, the source potential of the power MOSFET 1 is supplied from the plug PG1 to the n-type source region SR1 and to the p-type semiconductor region PR1 through the p-type semiconductor region PR2. The wiring M1A is connected to the load LD (see FIG. 1) via a conductive path outside the semiconductor device.

The back electrode BE is electrically connected to the n-type substrate body SB and is electrically connected to the n-type semiconductor layer EP through the n-type substrate body SB. Therefore, the drain potential of the power MOSFET 1 is supplied from the back electrode BE to the drain region (n-type substrate body SB and n-type semiconductor layer EP) of the power MOSFET 1. The back electrode BE is connected to the power supply potential VB (see FIG. 1) via a conductive path outside the semiconductor device. Therefore, the drain potential of the power MOSFET 1 is the power supply potential VB.

The wiring M1B is electrically connected to the gate wiring part TGL via the plug PG2. The gate potential of the power MOSFET 1 is supplied from the wiring M1B to the trench gate electrode TG via the plug PG2 and the gate wiring part TGL. The wiring M1B is connected to a control circuit in the semiconductor device via wiring in the semiconductor device.

The wiring M1D is electrically connected to the n-type drain region DR2 via the plug PGD. The drain potential of LDMOSFET 2 is supplied from the wiring M1D to the n-type drain region DR2 via the plug PGD. The drain potential of LDMOSFET 2 is, for example, the power supply potential VB.

The wiring M1S is electrically connected to the n-type source region SR2 via the plug PGS and is also electrically connected to the p-type semiconductor region PC via the plug PGP. That is, the wiring M1S is electrically connected to both the plug PGS arranged on the n-type source region SR2 and the plug PGP arranged on the p-type semiconductor region PC.

Therefore, the potential supplied to the n-type source region SR2 from the plug PGS (the source potential of LDMOSFET 2) and the potential supplied to the p-type semiconductor region PC from the plug PGP are the same. Consequently, the source potential of LDMOSFET 2 is supplied from the plug PGS to the n-type source region SR2 and from the plug PGP to the p-type well region PW2 via the p-type semiconductor region PC. The source potential of LDMOSFET 2 is, for example, the ground potential GND.

A gate wiring electrically connected to the gate electrode GE via a plug is formed on the insulating film IL, but the gate wiring is not shown in FIGS. 2 and 3.

The wiring M1A, the wiring M1B, the wiring M1D, and the wiring M1S are not connected to each other and are separated from each other.

In the case of FIGS. 2 and 3, the plug PGS and the plug PGP are connected to the common wiring M1S. There may be cases where the plug PGS is connected to the wiring M1S, and the plug PGP is connected to another wiring (not shown) formed on the insulating film IL. In such cases, since the wiring M1S connected to the plug PGS and the wiring (not shown) connected to the plug PGP are separated from each other, the potential supplied to the n-type source region SR2 from the plug PGS and the potential supplied to the p-type semiconductor region PC from the plug PGP can be controlled independently.

The illustration and description of the structure over the insulating film IL, the wiring M1A, the wiring M1B, the wiring M1D, and the wiring M1S are omitted.

### BACKGROUND OF THE STUDY

The inventor of the present application has been studying a semiconductor device having the power MOSFET 1 and the LDMOSFET 2.

The power MOSFET 1 is used as a power switching element. Therefore, it is desirable to reduce the on-resistance (resistance during conduction) of the power MOSFET 1.

When the power MOSFET 1 is turned off, a surge voltage may be superimposed on the drain voltage. Therefore, it is desirable to improve the breakdown voltage of the LDMOSFET 2 so that the LDMOSFET 2 can withstand (not be destroyed) when a voltage higher than the power supply potential VB is applied to the drain of LDMOSFET 2.

Therefore, to improve the performance of the semiconductor device having the power MOSFET 1 and athe LDMOSFET 2, it is desirable to achieve both the reduction of the on-resistance of the power MOSFET 1 and the improvement of the breakdown voltage of the LDMOSFET 2.

### MAIN FEATURES AND EFFECTS

To reduce the on-resistance of the power MOSFET 1, it is effective to increase the n-type impurity concentration of the n-type semiconductor layer EP. The operating current (on-current) of the power MOSFET 1 flows between the back electrode BE and the wiring M1A via the n-type substrate body SB, the n-type semiconductor layer EP, the channel formed in the p-type semiconductor region PR1, the n-type source region SR1, and the plug PG1. Therefore, by increasing the n-type impurity concentration of the n-type semiconductor layer EP, the electrical resistance of the n-type semiconductor layer EP can be reduced, thereby reducing the on-resistance of the power MOSFET 1.

In the case of FIG. 1, the wiring M1A is connected to the load LD located outside the semiconductor device, and the back electrode BE is connected to the power supply potential VB. The power supply potential VB supplied to the back electrode BE is supplied to the n-type semiconductor layer EP via the n-type substrate body SB. The drain potential (power supply potential VB) of the LDMOSFET 2 is supplied from the wiring M1D to the n-type drain region DR2 via the plug PGD and further supplied to the n-type drift region ND via the n-type drain region DR2. The source potential of the LDMOSFET 2 is supplied to the n-type source region SR2 via the plug PGS and to the p-type semiconductor region PC via the plug PGP and further supplied to the p-type well region PW1 via the p-type semiconductor region PC and the p-type well region PW2.

Therefore, a potential difference corresponding to the difference between the drain voltage (power supply potential VB) and the source voltage (ground potential GND) occurs between the p-type well region PW1 and the n-type semiconductor layer EP under the p-type well region PW1. Also, a potential difference corresponding to the difference between the drain voltage (power supply potential VB) and the source voltage (ground potential GND) occurs between the n-type drift region ND and the p-type well region PW1.

Therefore, when a surge voltage is superimposed on the drain voltage (power supply potential VB) of the LDMOSFET 2 during the turn-off of the power MOSFET 1, the breakdown voltage of the LDMOSFET 2 is determined by the breakdown voltage of the PN junction formed at the bottom surface 5 of the n-type drift region ND (the boundary between the n-type drift region ND and the p-type well region PW1) and the breakdown voltage of the PN junction formed at the bottom surface 6 of the p-type well region PW1 (the boundary between the p-type well region PW1 and the n-type semiconductor layer EP). Increasing the n-type impurity concentration of the n-type semiconductor layer EP acts to lower the breakdown voltage of the PN junction formed at the bottom surface 6 of the p-type well region PW1.

Here, the bottom surface 6 of the p-type well region PW1 has a bottom surface 6a located under the n-type drift region ND and a bottom surface 6b located under the p-type well region PW2.

Therefore, in the first embodiment, the p-type impurity concentration of the p-type well region PW1 is lowered. That is, the n-type impurity concentration of the n-type semiconductor layer EP is increased, and the p-type impurity concentration of the p-type well region PW1 is lowered.

By lowering the p-type impurity concentration of the p-type well region PW1, the depletion layer tends to spread in the p-type well region PW1 from the bottom surface 5 of the n-type drift region ND downward and from the bottom surface 6 of the p-type well region PW1 upward. As a result, the depletion layer spread downward from the bottom surface 5 of the n-type drift region ND and the depletion layer spreading upward from the bottom surface 6 of the p-type well region PW1 connect, allowing almost the entire p-type well region PW1 to be depleted under the n-type drift region ND. This prevents destruction at the PN junction formed at the bottom surface 5 of the n-type drift region ND when a surge voltage is superimposed on the drain voltage (power supply potential VB) of the LDMOSFET 2 and prevents destruction at the PN junction formed at the bottom surface 6a of the p-type well region PW1.

As a result, when a surge voltage is superimposed on the drain voltage (power supply potential VB) of the LDMOSFET 2, the breakdown voltage of the LDMOSFET 2 is not determined by the breakdown voltage of the PN junction formed at the bottom surface 5 of the n-type drift region ND, nor by the breakdown voltage of the PN junction formed at the bottom surface 6a of the p-type well region PW1, but is almost determined by the breakdown voltage of the PN junction formed at the bottom surface 6b of the p-type well region PW1. Since the n-type impurity concentration of the n-type drift region ND is higher than the n-type impurity concentration of the n-type semiconductor layer EP, the breakdown voltage of the PN junction formed at the bottom surface 6b of the p-type well region PW1 is higher than the breakdown voltage of the PN junction formed at the bottom surface 5 of the n-type drift region ND. Therefore, the breakdown voltage of the LDMOSFET 2 is not affected by the breakdown voltage of the PN junction formed at the bottom surface 5 of the n-type drift region ND, nor by the breakdown voltage of the PN junction formed at the bottom surface 6a of the p-type well region PW1, but is determined by the breakdown voltage of the PN junction formed at the bottom surface 6b of the p-type well region PW1, resulting in an improvement in the breakdown voltage of the LDMOSFET 2.

Therefore, the technical concept of the first embodiment is to increase the n-type impurity concentration of the n-type semiconductor layer EP and to lower the p-type impurity concentration of the p-type well region PW1. Therefore, in the first embodiment, the p-type impurity concentration of the p-type well region PW1 is lower than the n-type impurity concentration of the n-type semiconductor layer EP. More specifically, the p-type impurity concentration of the p-type well region PW1 is lower than the n-type impurity concentration of the n-type semiconductor layer EP under the p-type well region PW1. This allows for both the reduction of the on-resistance of the power MOSFET 1 and the improvement of the breakdown voltage of LDMOSFET 2, thereby improving the performance of the semiconductor device.

To accurately obtain the effect of reducing the on-resistance of the power MOSFET 1, it is preferable that the n-type impurity concentration of the n-type semiconductor layer EP is 1.0E16/cm³ or more and 1.0E17/cm³ or less. To accurately obtain the effect of improving the breakdown voltage of the LDMOSFET 2, it is preferable that the p-type impurity concentration of the p-type well region PW1 is 1.0E16/cm³ or more and 1.0E17/cm³ or less.

It is preferable to set the p-type impurity concentration of the p-type well region PW1 such that the entire p-type well region PW1 is depleted under the n-type drift region ND.

### SECOND EMBODIMENT

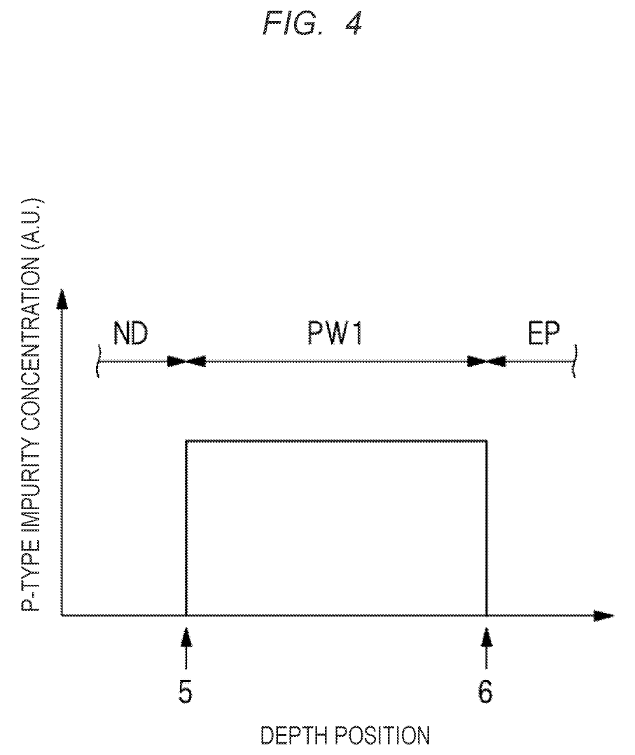

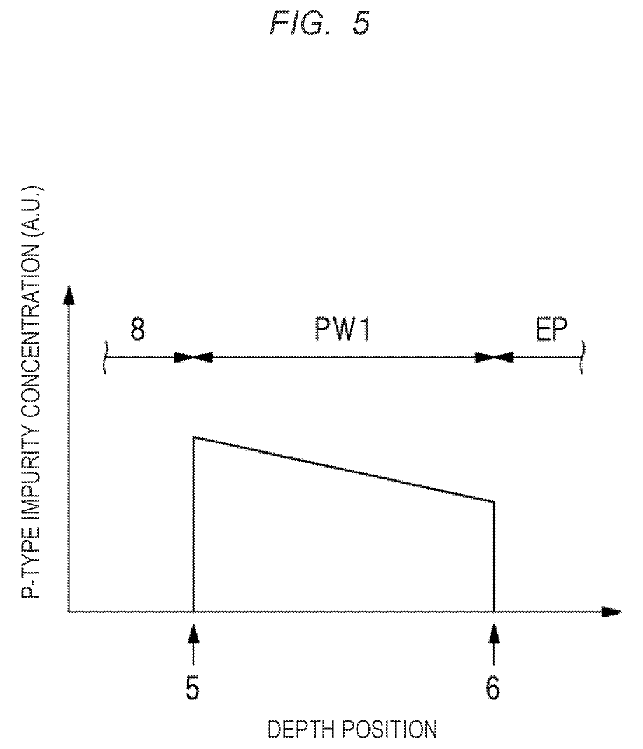

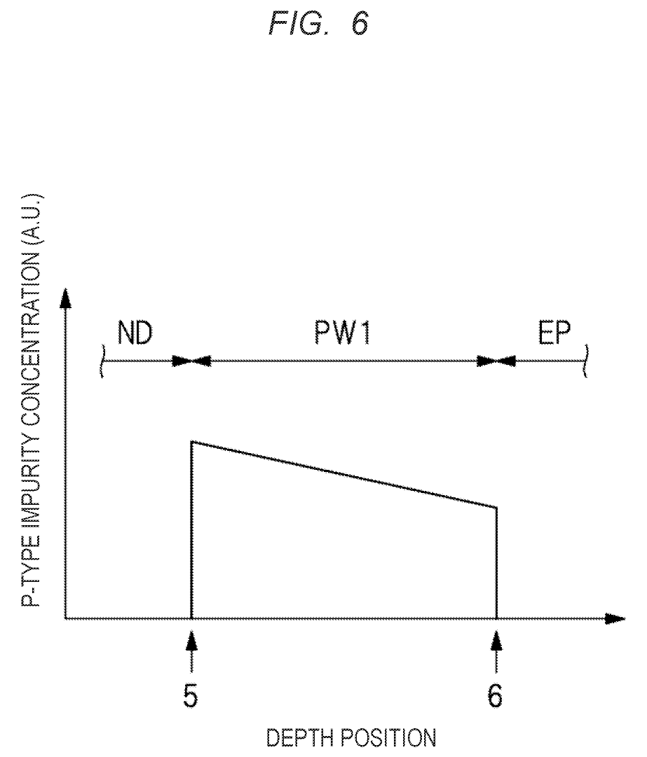

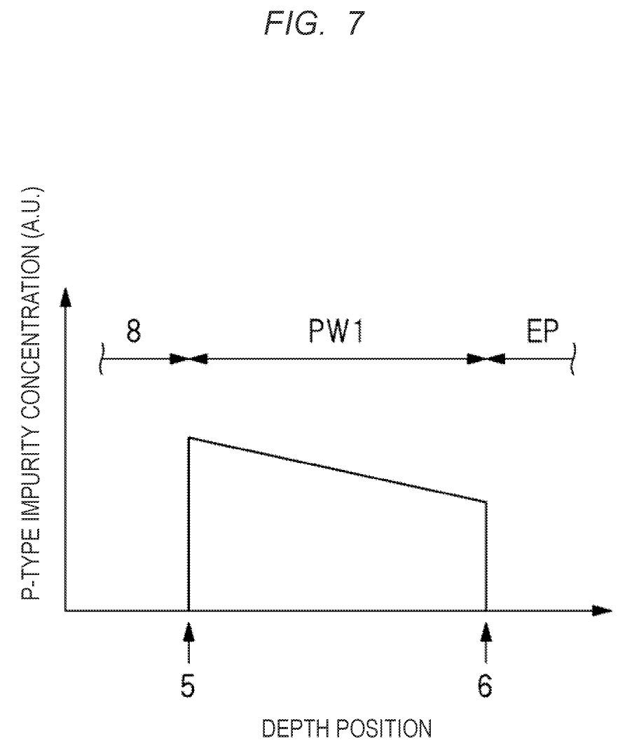

FIGS. 4 and 5 are graphs showing the p-type impurity concentration distribution in the p-type well region PW1 in the semiconductor device of the first embodiment, and FIGS. 6 and 7 are graphs showing the p-type impurity concentration distribution in the p-type well region PW1 in the semiconductor device of the second embodiment. The vertical axis of each graph indicates the p-type impurity concentration, and the horizontal axis of each graph indicates the depth position.

Note that FIGS. 4 and 6 show the p-type impurity concentration distribution in the p-type well region PW1 under the n-type drain region DR2. That is, FIGS. 4 and 6 show the p-type impurity concentration distribution in the p-type well region PW1 at the position along the dotted line L1 shown in FIG. 3. FIGS. 5 and 7 show the p-type impurity concentration distribution in the p-type well region PW1 under the side surface 8 of the n-type drift region ND. That is, FIGS. 5 and 7 show the p-type impurity concentration distribution at the position along the dotted line L2 shown in FIG. 3. The side surface (end) 8 of the n-type drift region ND overlaps the gate electrode GE2 in plan view and is adjacent to the channel of the LDMOSFET 2.

The difference between the semiconductor device of the first embodiment and the semiconductor device of the second embodiment is the p-type impurity concentration distribution in the p-type well region PW1.

In the case of the first embodiment, as shown in FIG. 4, the p-type impurity concentration in the p-type well region PW1 under the n-type drain region DR2 is almost constant regardless of the depth position in the p-type well region PW1. In the case of the first embodiment, as shown in FIG. 5, the p-type impurity concentration in the p-type well region PW1 under the side surface 8 of the n-type drift region ND gradually decreases as it becomes deeper (gradually decreases towards the bottom surface 6). Therefore, in the case of the first embodiment, the trend of the p-type impurity concentration distribution in the p-type well region PW1 under the side surface 8 of the n-type drift region ND differs from the trend of the p-type impurity concentration distribution in the p-type well region PW1 under the n-type drain region DR2. As a result, when the depletion layer spreads downward from the bottom surface 5 of the n-type drift region ND, the way the depletion layer spreads under the n-type drain region DR2 and under the side surface 8 of the n-type drift region ND tends to differ.

In contrast, in the case of the second embodiment, as shown in FIG. 6, the p-type impurity concentration in the p-type well region PW1 under the n-type drain region DR2 gradually decreases as it becomes deeper (gradually decreases towards the bottom surface 6). In the case of the second embodiment, as shown in FIG. 7, the p-type impurity concentration in the p-type well region PW1 under the side surface 8 of the n-type drift region ND gradually decreases as it becomes deeper (gradually decreases towards the bottom surface 6). Therefore, in the case of the second embodiment, the trend of the p-type impurity concentration distribution in the p-type well region PW1 under the side surface 8 of the n-type drift region ND is the same as the trend of the p-type impurity concentration distribution in the p-type well region PW1 under the n-type drain region DR2. This allows the depletion layer to spread almost uniformly downward from the bottom surface 5 of the n-type drift region ND, making it easier to deplete the entire p-type well region PW1 under the n-type drift region ND. As a result, when a surge voltage is superimposed on the drain voltage (power supply potential VB) of the LDMOSFET 2, it is possible to accurately prevent breakdown from occurring at the PN junction formed at the bottom surface 5 of the n-type drift region ND and at the PN junction formed at the bottom surface 6a of the p-type well region PW1. Therefore, the breakdown voltage of the LDMOSFET 2 can be further improved.

The invention made by the present inventor has been described above in detail based on the embodiment, but the present invention is not limited to the embodiment described above, and needless to say that various modifications can be made without departing from the gist thereof.

What is claimed is:

1. A semiconductor device comprising:
a semiconductor substrate having a main surface and a back surface opposite the main surface;
a first MOSFET formed at the main surface of the semiconductor substrate;
a second MOSFET formed at the main surface of the semiconductor substrate; and
a back electrode formed on the back surface of the semiconductor substrate,
wherein the semiconductor substrate comprises:
a substrate region of a first conductivity type; and
a semiconductor layer of the first conductivity type formed on the substrate region,
wherein the first MOSFET comprises:
a gate electrode formed on the semiconductor layer via a gate insulating film;
a first source region of the first conductivity type formed in the semiconductor layer;
a first drain region of the first conductivity type formed in the semiconductor layer;
a drift region of the first conductivity type formed in the semiconductor layer and in contact with a bottom surface of the first drain region;
a first well region of a second conductivity type opposite to the first conductivity type, formed in the semiconductor layer and in contact with a bottom surface of the first source region; and
a second well region of the second conductivity type formed in the semiconductor layer and in contact with a bottom surface of the drift region and a bottom surface of the first well region,
wherein the second MOSFET comprises:
a trench gate electrode formed in a trench of the semiconductor layer via a second gate insulating film;
a second source region of the first conductivity type formed in the semiconductor layer and adjacent to the trench gate electrode via the second gate insulating film; and
a first semiconductor region of the second conductivity type formed in the semiconductor layer, located under the second source region, and adjacent to the trench gate electrode via the second gate insulating film,
wherein the bottom surface of the drift region is shallower than a bottom surface of the second well region,
wherein the bottom surface of the first well region is shallower than the bottom surface of the second well region,
wherein the bottom surface of the first drain region is shallower than the bottom surface of the drift region,
wherein the bottom surface of the first source region is shallower than the bottom surface of the first well region,
wherein an impurity concentration of the first conductivity type in the first source region is higher than an impurity concentration of the first conductivity type in the drift region,
wherein an impurity concentration of the second conductivity type in the first well region is higher than an impurity concentration of the second conductivity type in the second well region, and
wherein the impurity concentration of the second conductivity type in the second well region is lower than an impurity concentration of the first conductivity type in the semiconductor layer.

2. The semiconductor device according to claim 1,
wherein the semiconductor layer located under the first semiconductor region and the substrate region located under the first semiconductor region function as the second drain region of the second MOSFET.

3. The semiconductor device according to claim 1,
wherein the first MOSFET comprises a second semiconductor region of the second conductivity type formed in the semiconductor layer,
wherein an impurity concentration of the second conductivity type in the second semiconductor region is higher than the impurity concentration of the second conductivity type in the first well region, and
wherein the first well region is in contact with the bottom surface of the first source region and a bottom surface of the second semiconductor region.

4. The semiconductor device according to claim 3, comprising:
an insulating film formed on the main surface of the semiconductor substrate and covering the gate electrode;
a first contact plug penetrating through the insulating film and electrically connected to the first drain region;
a second contact plug penetrating through the insulating film and electrically connected to the first source region; and
a third contact plug penetrating through the insulating film and electrically connected to the second semiconductor region.

5. The semiconductor device according to claim 4,
wherein a first fixed potential is supplied from the first contact plug to the first drain region,
wherein a second fixed potential different from the first fixed potential is supplied from the second contact plug to the first source region,
wherein the second fixed potential is supplied from the third contact plug to the second semiconductor region, and
wherein the first fixed potential is supplied from the back electrode to the substrate region.

6. The semiconductor device according to claim 5,
wherein the first conductivity type is n-type,
wherein the second conductivity type is p-type, and
wherein the first fixed potential is higher than the second fixed potential.

7. The semiconductor device according to claim 6,
wherein the second MOSFET is a power switching element.

8. The semiconductor device according to claim 1,
wherein a part of the gate electrode overlaps the drift region in plan view, and
wherein another part of the gate electrode overlaps the first well region.

9. The semiconductor device according to claim 1,
wherein the impurity concentration of the first conductivity type in the drift region is higher than the impurity concentration of the first conductivity type in the semiconductor layer.

10. The semiconductor device according to claim 1,
wherein under the first drain region, the impurity concentration of the second conductivity type in the second well region gradually decreases toward the bottom surface of the second well region,
wherein under a side surface of the drift region, the impurity concentration of the second conductivity type in the second well region gradually decreases toward the bottom surface of the second well region, and
wherein the side surface of the drift region overlaps the gate electrode in plan view.
